(19) United States
(12) Patent Application Publication
(10) Pub. No.: US 2011/0132430 A1
(43) Pub. Date: Jun. 9, 2011

(54) SOLAR ENERGY CONVERSION DEVICE AND MODULE

(75) Inventors: GA-LANE CHEN, Santa Clara, CA (US); TAI-CHERNG YU, Tu-Cheng (TW); HAN-LUNG LEE, Tu-Cheng (TW); SEI-PING LOUH, Tu-Cheng (TW); YUNG-LUN HUANG, Tu-Cheng (TW)

(73) Assignee: HON HAI PRECISION INDUSTRY CO., LTD., Tu-Cheng (TW)

(21) Appl. No.: 12/691,886

(22) Filed: Jan. 22, 2010

(30) Foreign Application Priority Data
Dec. 4, 2009 (CN) 200910310887.3

(51) Int. Cl. H01L 31/052; H01L 31/024

(52) U.S. Cl. 136/246; 136/259

(57) ABSTRACT

An exemplary solar energy conversion device includes a substrate, a solar energy conversion chip, and a carbon nanotube layer. The substrate defines a through hole. The solar energy conversion chip is positioned on the substrate and covers the through hole. The solar energy conversion chip includes a light incident surface facing away from the substrate and a heat dissipating surface at an opposite side thereof to the light incident surface. The carbon nanotube layer is formed on the heat dissipating surface.

### BACKGROUND

1. Technical Field

The present disclosure relates to solar energy conversion devices and related solar energy conversion modules.

2. Description of Related Art

Due to growing demand for clean energy, solar energy conversion modules are widely deployed nowadays. In such a conversion module, a solar energy conversion device converts sunlight into electrical energy. However, solar energy also causes a solar energy conversion chip of the solar energy conversion device to overheat, resulting in damage and/or reduced durability of the solar energy conversion chip.

Therefore, a solar energy conversion device and a related solar energy conversion module are needed.

### BRIEF DESCRIPTION OF THE DRAWINGS

FIG. 1 is an isometric and schematic view of a solar energy conversion device, according to a first exemplary embodiment.

FIG. 2 is a sectional view taken along line II-II of the solar energy conversion device of FIG. 1.

FIG. 3 is a schematic view of a method for making a carbon nanotube layer used in the solar energy conversion device of FIG. 1.

FIG. 4 is an enlarged schematic view of the carbon nanotube layer of FIG. 3.

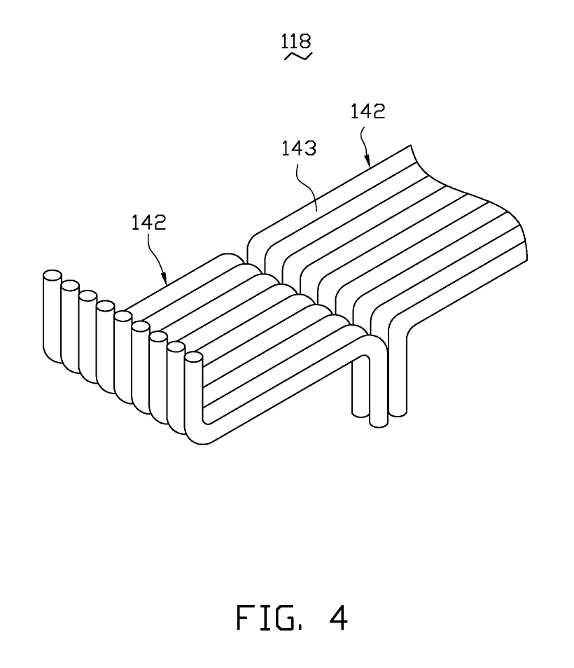

FIG. 5 is an isometric and schematic view of a solar energy conversion module, according to a second exemplary embodiment.

FIG. 6 is a sectional view of a solar energy conversion device, according to a third exemplary embodiment.

FIG. 7 is a sectional view of a solar energy conversion device, according to a fourth exemplary embodiment.

FIG. 8 is an isometric and schematic view of a solar energy conversion device, according to a fifth exemplary embodiment.

FIG. 9 is a sectional view taken along line IX-IX of the solar energy conversion device of FIG. 8.

FIG. 10 is a sectional view of a solar energy conversion device, according to a sixth exemplary embodiment.

FIG. 11 is a sectional view of a solar energy conversion device, according to a seventh exemplary embodiment.

### DETAILED DESCRIPTION

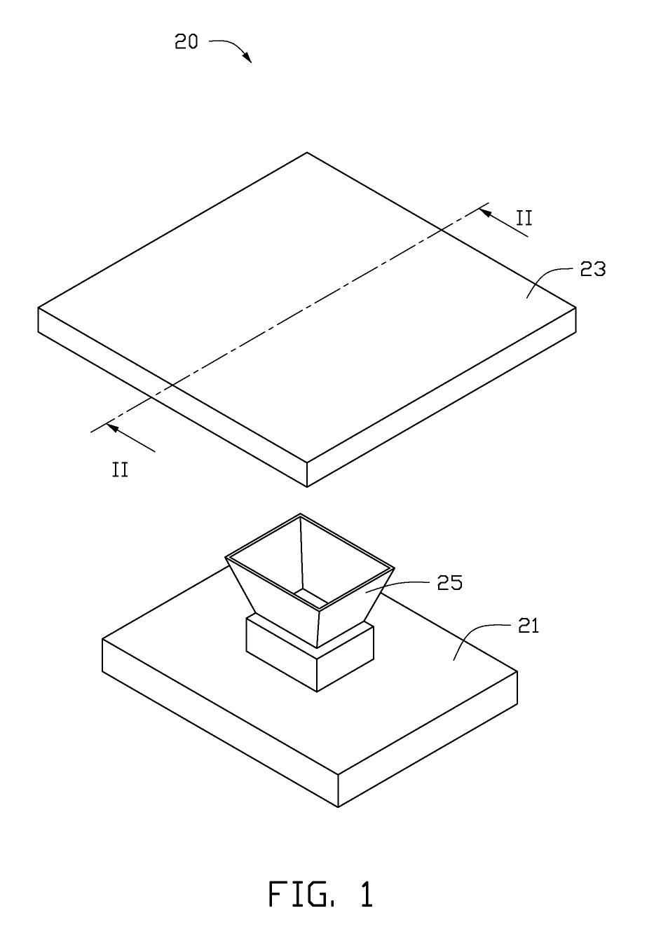

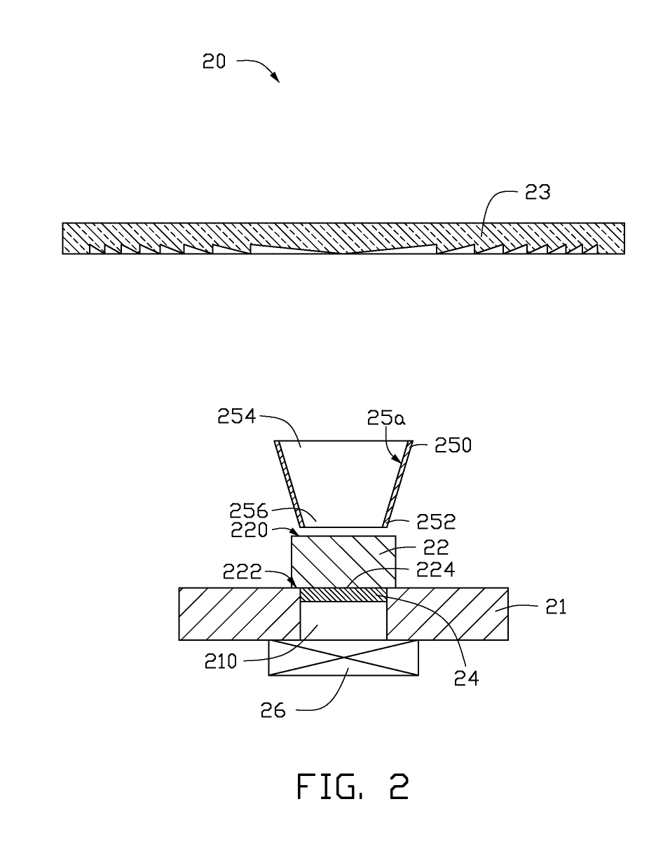

Referring to FIGS. 1 and 2, a solar energy conversion device 20, according to a first exemplary embodiment, includes a substrate 21, a solar energy conversion chip 22, a converging lens 23, and a carbon nanotube (CNT) layer 24.

The substrate 21 is substantially rectangular and may be a ceramic substrate. The substrate 21 defines a through hole 210.

The solar energy conversion chip 22 is positioned on the substrate 21 and covers the through hole 210. The solar energy conversion chip 22 is configured for converting solar energy into electrical energy. A material of the solar energy conversion chip 22 may be III-V type semiconductor in the periodic table of chemical elements, such as gallium arsenide, gallium aluminum arsenide, or indium phosphide.

The solar energy conversion chip 22 includes a light incident surface 220 facing away from the substrate 21 and a heat dissipating surface 222 at an opposite side thereof to the light incident surface 220. The heat dissipating surface 222 includes an area 224 exposed from the through hole 210.

The converging lens 23 is positioned apart from the solar energy conversion chip 22 and faces the light incident surface 220. The converging lens 23 is configured for converging light onto the light incident surface 220 of the solar energy conversion chip 22. In this embodiment, the converging lens 23 is a Fresnel lens.

The CNT layer 24 is formed on the heat dissipating surface 222. In this embodiment, the CNT layer 24 is formed on the exposed area 224 of the heat dissipating surface 222 in the through hole 210.

In this embodiment, the CNT layer 24 includes a plurality of CNTs substantially parallel to each other. The CNTs are substantially parallel to the heat dissipating surface 222.

Methods for making a CNT film may include a direct growth method, a flocculating method, a pressing method or a pulling method. The CNT film is attached to the exposed area 224 of the heat dissipating surface 222 to form the CNT layer 24.

The direct growth method is used to grow CNT films directly on a substrate.

The flocculating method for making a CNT film includes the following steps: adding a plurality of CNTs to a solvent to create a CNT floccule structure in the solvent; separating the CNT floccule structure from the solvent; and shaping the separated CNT floccule structure into the CNT film. The CNT film made by the flocculating method includes a plurality of isotropic CNTs twisted with each other and disorderly distributed therein.

The pressing method for making a CNT film includes the following steps: forming an array of CNTs on a substrate; and pressing the array of CNTs using a compressing apparatus, thereby forming a CNT film. The CNT film made by the pressing method includes a plurality of CNTs aligned in one or more directions.

In this embodiment, the pulling method is adopted to make the CNT film.

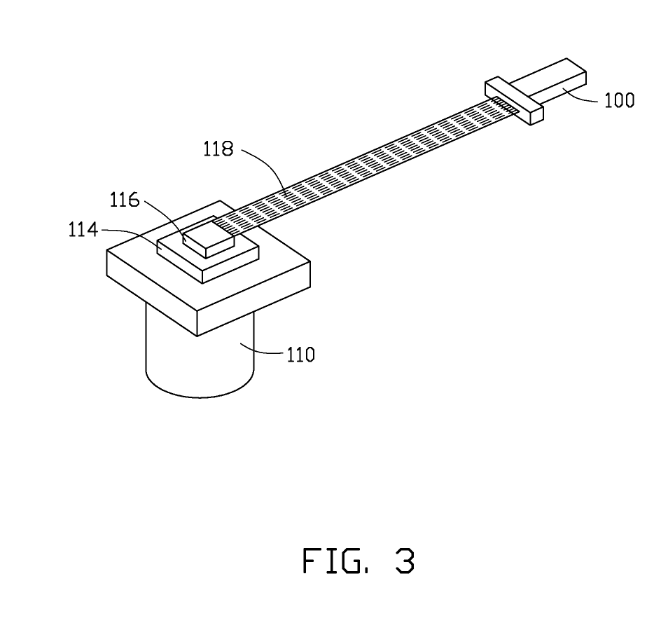

Referring to FIG. 3, in step (a), the pulling method includes the following sub-steps: (a1) providing a CNT array 116, specifically, a super-aligned CNT array 116, on a substrate 114; and (a2) pulling out a CNT film 118 from the CNT array 116 with a pulling tool 100 (e.g., adhesive tape, pliers, tweezers, or another tool allowing multiple CNTs to be gripped and pulled simultaneously).

In step (a1), the method for making the super-aligned CNT array 116 on the substrate 114 includes the following sub-steps: (a11) providing a substantially flat and smooth substrate 114; (a12) forming a catalyst layer on the substrate 114; (a13) annealing the substrate 114 with the catalyst layer thereon at a temperature ranging from 700° C. to 900° C. in air for about 30 to 90 minutes; (a14) heating the substrate 114 with the catalyst layer at a temperature ranging from 500° C. to 740° C. in a furnace with a protective gas therein; and (a15) supplying a carbon source gas into the furnace for about 5 to 30 minutes, and growing a super-aligned CNT array 116 from the substrate 114.

In step (a11), the substrate 114 can be a P-type silicon wafer, an N-type silicon wafer, or a silicon wafer with a film of silicon dioxide thereon. A 4-inch P-type silicon wafer is used as the substrate 114 of the present example.

In step (a12), the catalyst layer can be made of iron (Fe), cobalt (Co), nickel (Ni), or any alloy thereof.

In step (a14), the protective gas can be made up of at least one of nitrogen (N₂), ammonia (NH₃), and a noble gas. In step (a15), the carbon source gas can be a hydrocarbon gas, such as ethylene (C₂H₄), methane (CH₄), acetylene (C₂H₂), ethane (C₂H₆), or any combination thereof.

The super-aligned CNT array 116 can be approximately 200 to 400 microns in height and includes a plurality of CNTs parallel to each other and substantially perpendicular to the substrate 114. The super-aligned CNT array 116 formed under the above conditions is essentially free of impurities, such as carbonaceous or residual catalyst particles. The CNTs in the super-aligned CNT array 116 are packed together closely by van der Waals attractive force.

In the present example, the substrate 114 is fixed on a sample platform 110 by an adhesive tape or a binding admixture. Alternatively, the substrate 114 is mechanically fixed on the sample platform 110.

In step (a2), the CNT film 118 can be formed by the following sub-steps: (a21) selecting a plurality of CNTs having a predetermined width from the super-aligned CNT array 116, binding the CNTs to the pulling tool 100; and (a22) pulling the CNTs at an even/uniform speed to achieve the CNT film 118.

In step (a21), the CNTs having a predetermined width can be selected by using a wide adhesive tape as the tool to contact the super-aligned CNT array 116. In step (a22), the pulling direction is substantially perpendicular to the growing direction of the super-aligned CNT array 116.

During the pulling process, initial CNTs segments are drawn out, other CNT segments are also drawn out end-to-end due to the van der Waals attractive force between ends of adjacent segments. This process of drawing ensures a successive CNT film 118 can be formed. The CNTs of the CNT film 118 are all substantially parallel to the pulling direction and connected end-to-end.

Width of the CNT film 118 depends on the size of the CNT array 116. Length of the CNT film 118 is arbitrary and may be determined according to need. In the present example, when the size of the substrate 114 is 4 inches, the width of the CNT film 118 approximately ranges from 1 to 10 centimeters, and the thickness of the CNT film 118 approximately ranges from 0.01 to 100 microns.

The CNT film 118 is adhesive because the CNTs have relatively large specific areas so that the CNT film 118 can be directly attached to the exposed area 224 of the heat dissipating surface 222 to form the CNT layer 24. More specifically, the CNT layer 24 includes at least two stacked CNT films 118. An angle α between the aligned directions of stacked CNTs in two adjacent CNT films 118 is in a range of 0°≦α≦90°.

In alternative embodiments, the super-aligned CNT array 116 can be attached to the exposed area 224 of the heat dissipating surface 222 along the growing direction of the CNTs in the super-aligned CNT array 116. Under this condition, the CNTs are substantially perpendicular to the heat dissipating surface 222.

In the first exemplary embodiment, to increase solar energy utilization and heat dissipation, the conversion device 20 further includes a light collecting device 25 and a fan 26.

The light collecting device 25 is substantially a hollow rectangular funnel and includes a first end 250 and a second end 252 at opposite sides thereof. The light collecting device 25 has a decreasing size from the first end 250 to the second end 252. The first end 250 faces the converging lens 23 and defines a first opening 254. The second end 252 faces the light incident surface 220 and defines a second opening 256. The first opening 254 is aligned and communicates with the second opening 256. A diameter of the first opening 254 is larger than that of the second opening 256. An orthogonal projection of the second opening 256 is substantially equal to or smaller than an area of the light incident surface 220 to ensure complete transmission of light from the second opening 256 to the light incident surface 220. An inner surface 25a of the light collecting device 25 is a light reflective surface. The light collecting device 25 collects the light passing through the converging lens 23 towards the light incident surface 220.

The fan 26 is an exhaust fan positioned on the substrate 21 covering the through hole 210. The fan 26 and the solar energy conversion chip 22 are positioned at opposite sides of the substrate 21. The fan 26 can take heat away from the CNT layer 24.

In use, the CNT layer 24 dissipates heat generated by the solar energy conversion chip 22 while the fan 26 accelerates heat dissipation. This increases the life of the solar energy conversion chip 22. Furthermore, due to conductivity, the CNT layer 24 can be used as to electrically conduct the electrical energy converted by the solar energy conversion chip 22 to an outer circuit/electronic device (not shown).

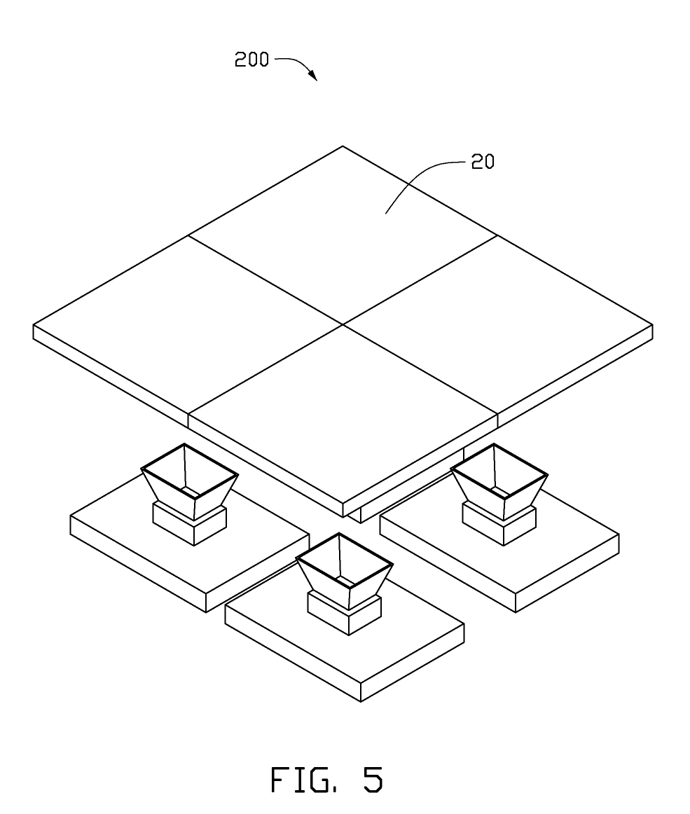

Referring to FIG. 5, a solar energy conversion module 200, according to a second exemplary embodiment, includes a plurality of solar energy conversion devices 20 arranged in an array. The electrical energy is collected from the solar energy conversion devices 20.

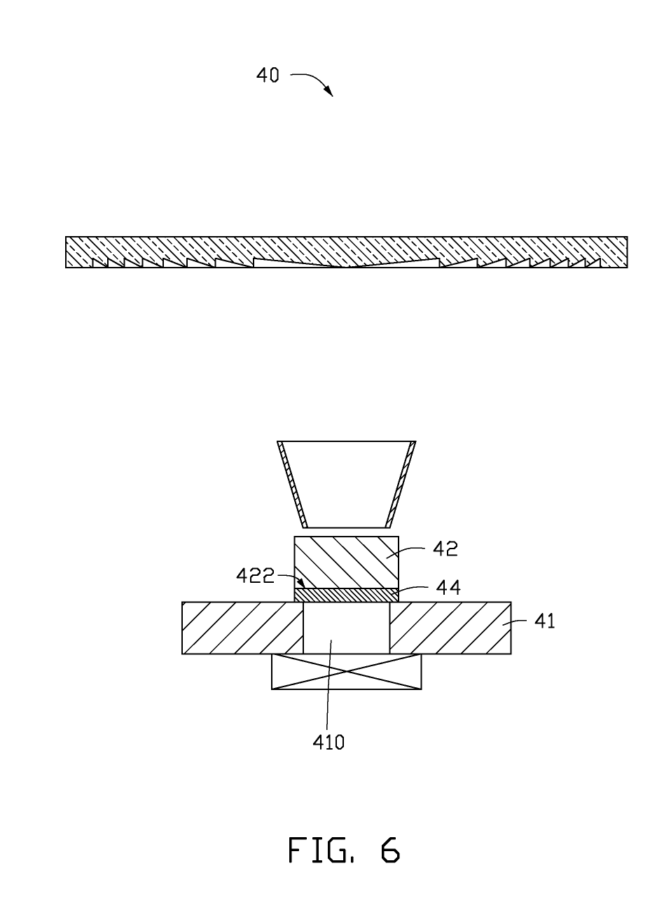

Referring to FIG. 6, a solar energy conversion device 40, according to a third exemplary embodiment, is shown. The difference between the solar energy conversion devices 40 and the solar energy conversion device 20 of the first embodiment, is a CNT layer 44 within the solar energy conversion device 40, is positioned differently.

The CNT layer 44 is positioned between the substrate 41 and the solar energy conversion chip 42. The CNT layer 44 is formed on the heat dissipating surface 422 and covers the through hole 410.

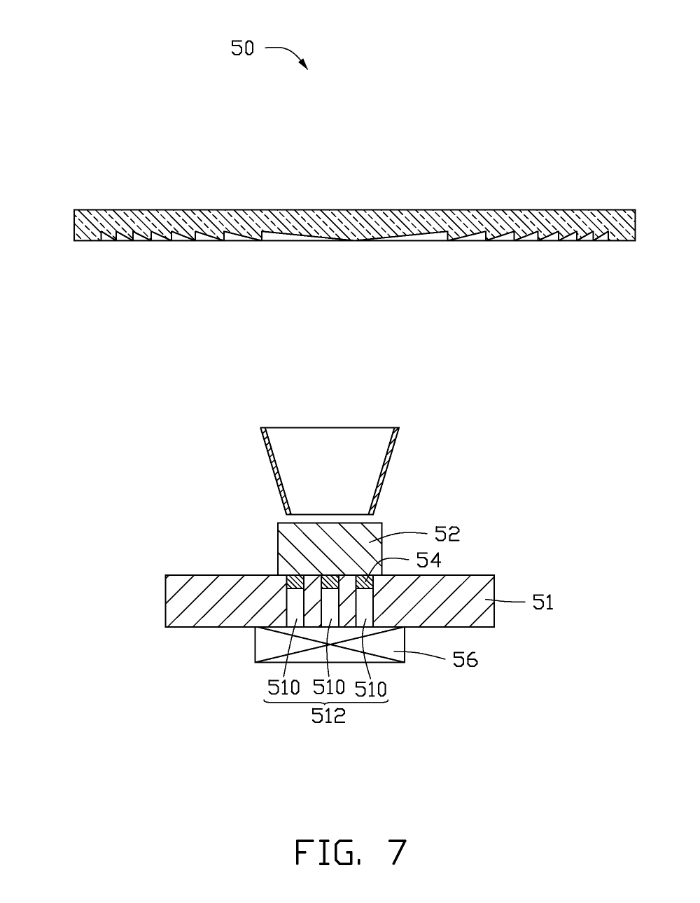

Referring to FIG. 7, a solar energy conversion device 50, according to a fourth exemplary embodiment, is shown. The differences between the solar energy conversion device 50 and the solar energy conversion device 20 of the first embodiment are that in the solar energy conversion device 50, a substrate 51 defines a plurality of through holes 510 and the solar energy conversion device 50 includes a plurality of CNT layers 54.

The through holes 510 form a through hole group 512. The solar energy conversion chip 52 covers the through hole group 512. The CNT layer 54 is received in the respective through hole 510. The fan 56 covers the through hole group 512.

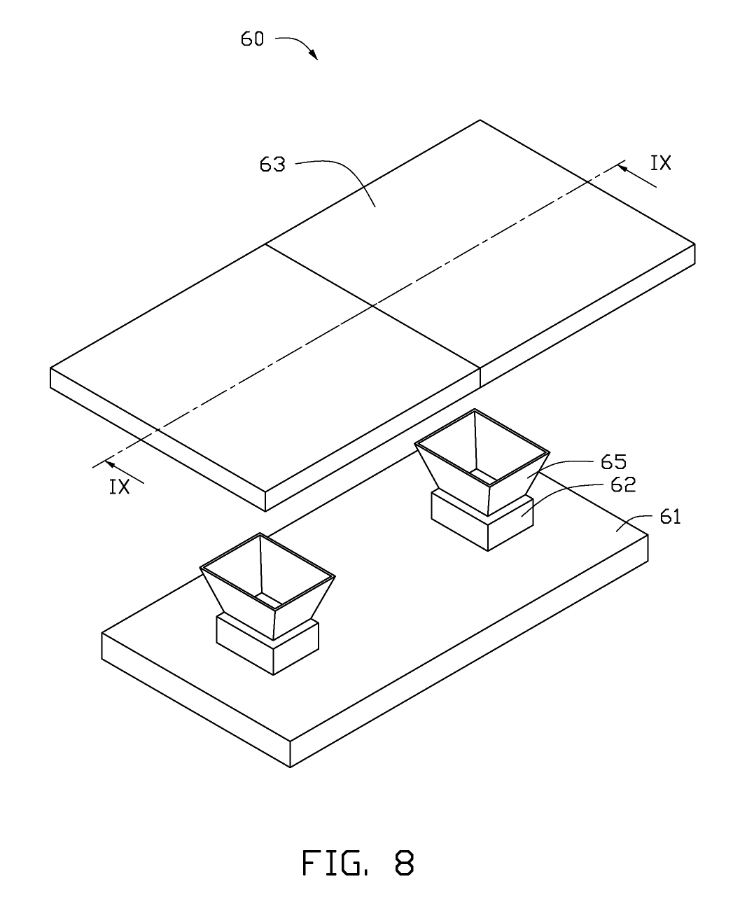

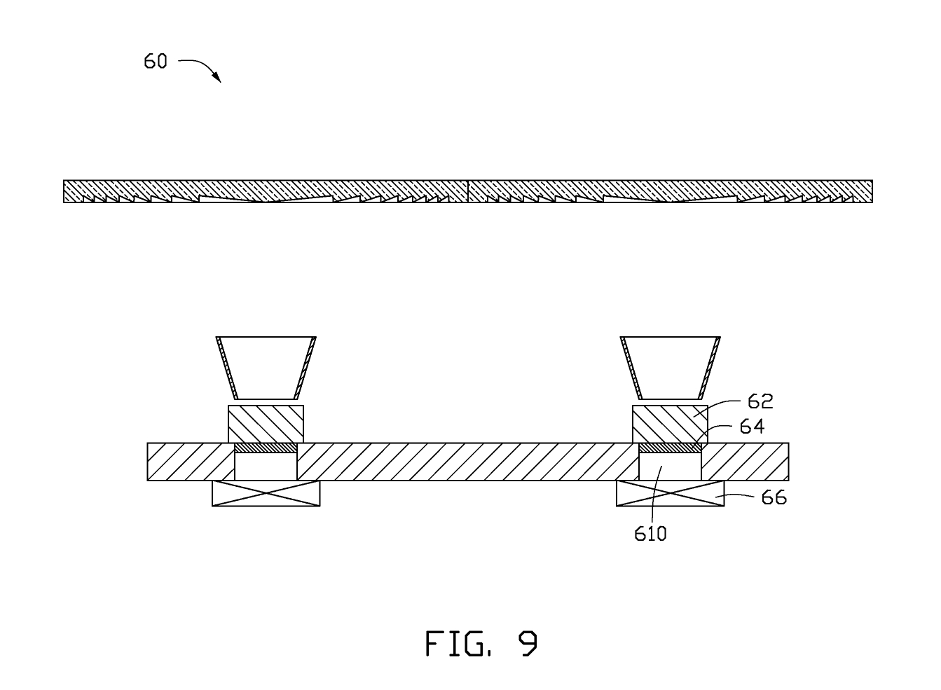

Referring to FIGS. 8 and 9, a solar energy conversion device 60, according to a fifth exemplary embodiment, includes a substrate 61, two solar energy conversion chips 62, two converging lenses 63, two CNT layers 64, two light collecting devices 65, and two fans 66.

The substrate 61 defines two spaced apart through holes 610. Each solar energy conversion chip 62 is positioned on the substrate 61 and covers a corresponding through hole 610.

Configurations of the solar energy conversion chip 62, the converging lens 63, the CNT layer 64, the light collecting device 65 and the fan 66 are substantially identical to those of the solar energy conversion chip 22, the converging lens 23, the CNT layer 24, the light collecting device 25 and the fan 26 of the solar energy conversion device 20 of the first embodiment.

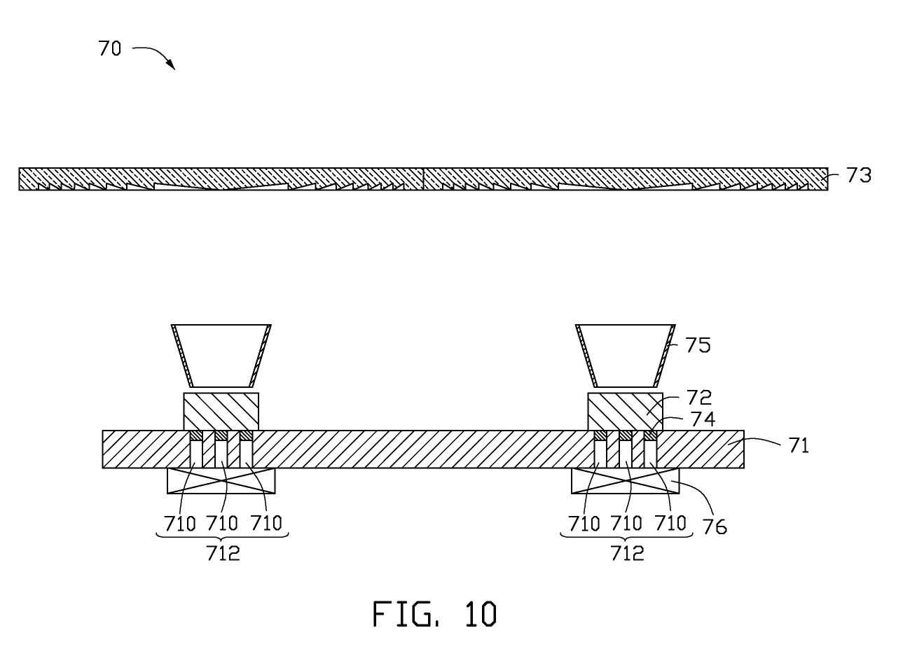

Referring to FIG. 10, a solar energy conversion device 70, according to a sixth exemplary embodiment, includes a substrate 71, two solar energy conversion chips 72, two converging lenses 73, a plurality of CNT layers 74, two light collecting devices 75, and two fans 76.

The substrate 71 defines a plurality of through holes 710. The through holes 710 form two through hole groups 712. The two through hole groups 712 are spaced from each other. Each solar energy conversion chip 72 is positioned on the substrate 71 and covers a corresponding through hole group 712. Each CNT layer 74 is received in a corresponding through hole 710.

Configurations of the converging lens 73, the light collecting device 75 and the fan 76 are substantially identical to those of the converging lens 23, the light collecting device 25 and the fan 26 of the solar energy conversion device 20 of the first embodiment.

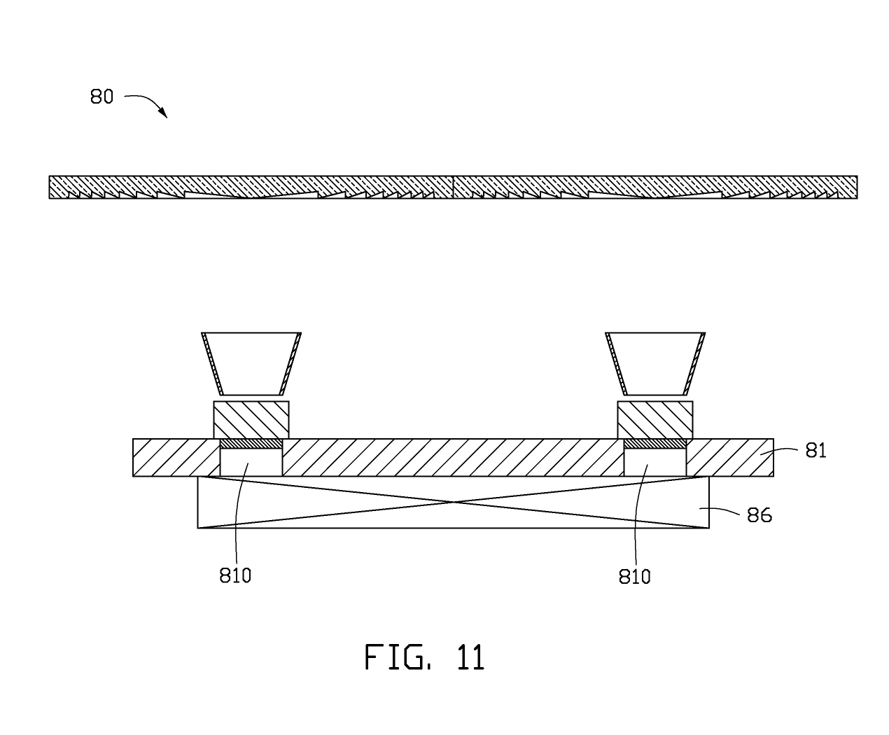

Referring to FIG. 11, a solar energy conversion device 80, according to a seventh exemplary embodiment, is shown. The difference between the solar energy conversion device 80 and the solar energy conversion device 60 of the fifth embodiment is that the solar energy conversion device 80 includes a fan 86. The fan 86 covers the two through holes 810.

The solar energy conversion module 200 of the second exemplary embodiment and the solar energy conversion devices of the third to seventh exemplary embodiments share identical advantages as the solar energy conversion device 20 of the first exemplary embodiment .

It is to be understood that, in alternative embodiments, the CNT layer can be positioned between the solar energy conversion chip and the substrate, and covers a corresponding through hole or a corresponding through hole group. The fan can cover a plurality of through hole groups.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A solar energy conversion device, comprising:
a substrate defining at least one through hole;
at least one solar energy conversion chip positioned on the substrate and covering the at least one through hole, the at least one solar energy conversion chip comprising a light incident surface facing away from the substrate and a heat dissipating surface at an opposite side thereof to the light incident surface; and
at least one carbon nanotube layer formed on the heat dissipating surface.

2. The solar energy conversion device of claim 1, wherein the at least one carbon nanotube layer is received in the at least one through hole.

3. The solar energy conversion device of claim 1, wherein the at least one carbon nanotube layer comprises a plurality of isotropic carbon nanotubes twisted with each other and disorderly distributed therein.

4. The solar energy conversion device of claim 1, wherein the at least one carbon nanotube layer comprises a plurality of carbon nanotubes substantially parallel to each other.

5. The solar energy conversion device of claim 4, wherein the parallel carbon nanotubes are substantially parallel to the heat dissipating surface.

6. The solar energy conversion device of claim 4, wherein the parallel carbon nanotubes are substantially perpendicular to the heat dissipating surface.

7. The solar energy conversion device of claim 1, further comprising at least one converging lens facing the light incident surface, the at least one converging lens configured for converging light onto the light incident surface of the at least one solar energy conversion chip.

8. The solar energy conversion device of claim 7, further comprising at least one light collecting device positioned between the at least one converging lens and the at least one solar energy conversion chip.

9. The solar energy conversion device of claim 1, further comprising at least one fan positioned on the substrate and covering the at least one through hole, the at least one fan and the at least one solar energy conversion chip positioned at opposite sides of the substrate.

10. The solar energy conversion device of claim 7, wherein the at least one converging lens is a Fresnel lens.

11. The solar energy conversion device of claim 1, wherein the at least one carbon nanotube layer is positioned between the substrate and the at least one solar energy conversion chip and covers the at least one through hole.

12. The solar energy conversion device of claim 1, wherein the at least one through hole comprises a plurality of through holes, and the at least one solar energy conversion chip comprises a plurality of solar energy conversion chips each covering a corresponding through hole.

13. The solar energy conversion device of claim 1, wherein the at least one through hole comprises a plurality of through holes, the through holes forming at least one through hole group, the at least one solar energy conversion chip covering the at least one through hole group.

14. The solar energy conversion device of claim 13, wherein the at least one through hole group comprises a plurality of through hole groups, and the at least one solar energy conversion chip comprises a plurality of solar energy conversion chips each covering a corresponding through hole group.

15. The solar energy conversion device of claim 9, wherein the at least one through hole comprises a plurality of through holes, and the at least one fan covers the through holes.

16. A solar energy conversion module, comprising:
a plurality of solar energy conversion devices arranged in an array, the solar energy conversion device, comprising:
a substrate defining at least one through hole;
at least one solar energy conversion chip positioned on the substrate and covering the at least one through hole, the at least one solar energy conversion chip comprising a light incident surface facing away from the substrate and a heat dissipating surface at an opposite side thereof to the light incident surface; and
at least one carbon nanotube layer formed on the heat dissipating surface.
